(19) United States
(12) Patent Application Publication
(10) Pub. No.: US 2026/0196261 A1
(43) Pub. Date: Jul. 9, 2026

(54) THREE-DIMENSIONAL DYNAMIC RAM WORD LINE COMB STRUCTURE

(71) Applicant: Micron Technology, Inc., Boise, ID (US)

(72) Inventor: Daniele Vimercati, El Dorado Hills, CA (US)

(21) Appl. No.: 19/416,620

(22) Filed: Dec. 11, 2025

Related U.S. Application Data
(60) Provisional application No. 63/743,056, filed on Jan. 8, 2025.

(51) Int. Cl. G11C 11/408; G11C 5/06; H10B 12/00

(52) U.S. Cl. CPC G11C 11/4085; G11C 5/063; G11C 11/4087; H10B 12/482; H10B 12/488

(57) ABSTRACT

A memory device may comprise a plurality of word lines comprising a portion of a first layer of the memory device. The plurality of word lines may comprise a first word line including a first trunk at least first and second branches that extend from, and are electrically connected to, the first trunk. The plurality of word lines may further comprise a second trunk and at least third and fourth branches that extend from, and are electrically coupled to, the second trunk. The second word line may be electrically decoupled from the first word line. The first and second branches of the first word line may be interleaved with the third and fourth branches of the second word line in the first layer of the memory device.

### PRIORITY APPLICATION

This application claims the benefit of priority to U.S. Provisional Application Ser. No. 63/743,056, filed Jan. 8, 2025, which is incorporated herein by reference in its entirety.

### TECHNICAL FIELD

The present disclosure relates to memory devices, including word line drivers for multiple-die memory arrays or memory devices.

### BACKGROUND

Memory devices store information in various electronic devices such as computers, wireless communication devices, cameras, digital displays, and the like. Information is stored by programming memory cells within a memory device to various states. For example, binary memory cells can be programmed to one of two supported states, often denoted by a logic 1 or a logic 0. In some examples, a single memory cell can support more than two states, any one of which can be stored. To access the stored information, a component of the device can read, or sense, at least one stored state in the memory device. To store information, a component of the device can write, or program, the state in the memory device.

Memory devices include magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), and others. Memory devices can be volatile or non-volatile. Non-volatile memory, such as FeRAM, can be configured to store logical state information for extended time periods in the absence of an external power source. Volatile memory devices, such as DRAM, can lose stored logical state information when disconnected from an external power source. In some examples, an FeRAM-based device can have a storage density similar to that of a volatile memory device, however the FeRAM-based device can have non-volatile properties due to the use of a ferroelectric capacitor as a storage device.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates an example of a memory architecture.

FIG. 2 illustrates generally a memory cell array structure with interleaved word line branches with respective driver tabs and pillars.

FIG. 3 illustrates generally a perspective view of a three-dimensional memory device structure with interleaved word lines.

FIG. 4 illustrates generally an example of two memory cell arrays.

FIG. 5 illustrates generally an example method for forming interleaved word line branches in a first layer of a memory device in accordance with examples described herein.

FIG. 6 illustrates generally an example method for forming driver tabs and conductive pillars to connect word lines in different layers to their respective driver circuits in accordance with examples described herein.

### DETAILED DESCRIPTION

Memory devices may include arrangements of memory cells and supporting circuitry formed over a substrate, such as a semiconductor substrate (e.g., a wafer of crystalline semiconductor, such as crystalline silicon). For example, a memory device may include one or more decks of memory cells over a substrate (e.g., of a memory die), where a deck may refer to a plane or level of memory cells above and parallel to the substrate. The one or more decks of memory cells may be associated with various arrangements of access line conductors, including access line conductors extending along one or more directions over a substrate. In some examples, circuitry for accessing the memory cells of a memory device (e.g., circuitry for selecting, accessing, or biasing access line conductors), such as driver circuitry, decoder circuitry, and other circuitry of the memory device may include transistors that are formed at least in part from doped portions of a substrate of a memory die (e.g., substrate-based transistors, transistors having channels formed from doped crystalline silicon or another semiconductor). As memory devices scale with a greater quantity of memory cells (e.g., a greater density of memory cells over a memory die substrate, or a greater quantity of layers or decks of memory cells above a memory die substrate, or both), the area of a substrate of a memory die for conductors or other circuitry to access the memory cells may increase, which may in turn lead to various limitations. For example, a total available surface area of a die is limited, so it can be desirable to maximize the die area used for storage and minimize the portions used to access the storage elements.

Memory devices, such as three-dimensional (3D) DRAM, may include access lines (e.g., word lines, digit lines, etc.) arranged in a pattern or grid. In some examples, access or driver portions of the word lines may include or use a tiered structure. Such a structure may facilitate the connection of word lines to a substrate or other circuitry through co-located or peripheral pillars that extend from the word lines to corresponding drivers, such as CMOS (Complementary Metal-Oxide-Semiconductor) drivers. Digit lines may extend vertically through multiple layers of memory cells. The arrangement of these structures may allow for more efficient operation and integration of memory cells within the compact space of modern memory devices.

The memory devices disclosed herein can include or use a word line structure that may help improve density and performance in 3D DRAM architectures. In an example, the structure comprises a plurality of word lines arranged in one or more layers of the memory device, with each word line including a trunk and multiple branches extending from the trunk. The branches of different word lines within a layer may be interleaved, allowing for more efficient use of space and improved access to memory cells.

In an example, a first layer of the memory device may include a first word line with a first trunk and at least first and second branches electrically coupled to and extending from the first trunk. Each of the first and second branches can be connected to memory cells corresponding to the first layer of the memory device. A second word line in the same layer may comprise a second trunk and at least third and fourth branches electrically coupled to and extending from the second trunk. Each of the third and fourth branches can be connected to memory cells corresponding to the first layer of the memory device. In an example, the first and second word lines may be electrically decoupled from each other, while their respective branches are interleaved within the layer. Thus, the branches of the first and second word lines may be interposed between, and coplanar with each other to form an interleaved arrangement of the word line branches.

Such an interleaved structure may allow for a more compact arrangement of memory cells and improved addressing capabilities. For example, a first group of memory cells in the layer may be electrically coupled to the first branch of the first word line, while a second group of memory cells in the same layer may be coupled to the second branch of the first word line. A third group of memory cells may be coupled to a branch of the second word line, with this branch interposed between and coplanar with the branches of the first word line.

To facilitate connection to driver circuitry, the word lines may include or be coupled to driver tabs extending laterally from their trunks. These driver tabs may be arranged in a staggered or offset manner between layers, allowing for efficient vertical connections through pillars to word line driver circuits. Stated differently, the driver tabs may extend laterally away from the word line trunks at different layers with a first driver tab and a second driver tab being laterally adjacent (or on opposite sides of the memory device) along an axis of the trunks of the word lines. This arrangement provides a compact, tiered structure and enables more densely arranged memory structures.

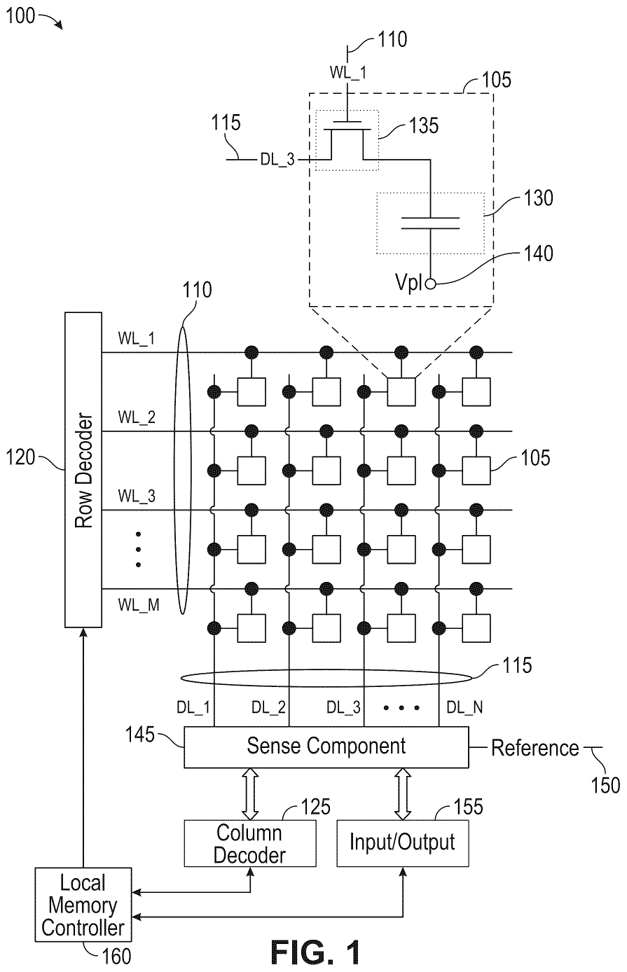

FIG. 1 illustrates an example of a memory architecture 100. In some examples, the memory architecture can support multiple-die memory devices. In some examples, the memory architecture 100 may be implemented as part of a memory chip, a memory device, or an electronic memory apparatus. The memory architecture 100 may include one or more memory cells 105 that may be programmable to store different logic states (e.g., programmed to one of two or more possible states). For example, a memory cell 105 may be operable to store one bit of information at a time (e.g., a logic 0 or a logic 1). In some examples, a memory cell 105 (e.g., a multi-level memory cell) may be operable to store more than one bit of information at a time (e.g., a logic 00, logic 01,logic 10, a logic 11, etc.).

In some examples, a memory cell 105 may store a charge representative of the programmable states in a capacitor. DRAM architectures may include a capacitor that includes a dielectric material to store a charge representative of the programmable state. In other memory architectures, other storage devices and components may be possible. For example, nonlinear dielectric materials may be employed (e.g., in a ferroelectric memory architecture). The memory cell 105 may include a logic storage component, such as a capacitor 130, and a switching component 135 (e.g., a cell selection component). The capacitor 130 may be an example of a dielectric capacitor or a ferroelectric capacitor. A node of the capacitor 130 may be coupled with a voltage source 140, which may be the cell plate reference voltage, such as Vpl, or may be ground, such as Vss.

The memory architecture 100 may include access lines (e.g., word lines 110 and digit lines 115) arranged in a pattern, such as a grid-like pattern. An access line may be a conductive line coupled with a memory cell 105 and may be used to perform access operations on the memory cell 105. In some examples, word lines 110 may be referred to as row lines. In some examples, digit lines 115 may be referred to as column lines or bit lines. References to access lines, row lines, column lines, word lines, digit lines, or bit lines, or their analogues, are generally interchangeable. The memory cells 105 may be positioned at intersections of the word lines 110 and the digit lines 115.

Operations such as reading and writing may be performed on the memory cells 105 by activating access lines such as a word line 110 or a digit line 115. By biasing a word line 110 and a digit line 115 (e.g., applying a signal such as a voltage to the word line 110 or the digit line 115), a single memory cell 105 may be accessed at their intersection. The intersection of a word line 110 and a digit line 115 may be referred to as an address of a memory cell 105. Activating a word line 110 or a digit line 115 may include applying a signal (e.g., a voltage) to the respective line.

Accessing the memory cells 105 may be controlled through a row decoder 120, or a column decoder 125, or any combination thereof. For example, a row decoder 120 may receive a row address from the local memory controller 160 and activate a word line 110 based on the received row address. A column decoder 125 may receive a column address from the local memory controller 160 and may activate a digit line 115 based on the received column address.

Selecting or deselecting the memory cell 105 may be accomplished by activating or deactivating the corresponding switching component 135 using a word line 110. The capacitor 130 may be coupled with the digit line 115 using the switching component 135. For example, the capacitor 130 may be isolated from the digit line 115 when the switching component 135 is deactivated, and the capacitor 130 may be coupled with digit line 115 when the switching component 135 is activated.

In an example, a word line 110 may be a conductive line in electronic communication with a memory cell 105 that is used to perform access operations on the memory cell 105. In some architectures, the word line 110 may be coupled with a gate of a switching component 135 of a memory cell 105 and may be operable to control the switching component 135 of the memory cell. In some architectures, the word line 110 may be coupled with a node of the capacitor of the memory cell 105 and the memory cell 105 may not include a switching component.

In an example, a digit line 115 may be a conductive line that couples the memory cell 105 with a sense component 145. In some architectures, the memory cell 105 may be selectively coupled with the digit line 115 during portions of an access operation. For example, the word line 110 and the switching component 135 of the memory cell 105 may be operable to couple or isolate the capacitor 130 of the memory cell 105 and the digit line 115. In some architectures, the memory cell 105 may be coupled with the digit line 115.

The sense component 145 may be operable to detect a state (e.g., a charge) stored on the capacitor 130 of the memory cell 105 and determine a logic state of the memory cell 105 based on the stored state. The sense component 145 may include one or more sense amplifiers to amplify or otherwise convert a signal resulting from accessing the memory cell 105. The sense component 145 may compare a signal detected from the memory cell 105 to a reference 150 (e.g., a reference voltage). The detected logic state of the memory cell 105 may be provided as an output of the sense component 145 (e.g., to an input/output 155), and may indicate the detected logic state to another component of a memory device that includes the memory architecture 100.

The local memory controller 160 may control the accessing of memory cells 105 through the various components (e.g., row decoder 120, column decoder 125, sense component 145). In some examples, one or more of the row decoder 120, column decoder 125, and sense component 145 may be co-located with the local memory controller 160. The local memory controller 160 may be operable to receive one or more of commands or data from one or more different memory controllers (e.g., an external memory controller associated with a host device, another controller associated with the memory architecture 100), translate the commands or the data (or both) into information that can be used by the memory architecture 100, perform one or more operations on the memory architecture 100, and communicate data from the memory architecture 100 to a host (e.g., a host device) based on performing the one or more operations. The local memory controller 160 may generate row signals and column address signals to activate the target word line 110 and the target digit line 115. The local memory controller 160 may generate and control various signals (e.g., voltages, currents) used during the operation of the memory architecture 100. In general, the amplitude, the shape, or the duration of an applied voltage or current discussed herein may be varied and may be different for the various operations discussed in operating a device corresponding to the memory architecture 100.

The local memory controller 160 may be operable to perform one or more access operations on one or more memory cells 105 of the memory architecture 100. Examples of access operations may include a write operation, a read operation, a refresh operation, a precharge operation, or an activate operation, among others. In some examples, access operations may be performed by or otherwise coordinated by the local memory controller 160 in response to various access commands (e.g., from a host device). The local memory controller 160 may be operable to perform other access operations not listed here or other operations related to the operating of the memory architecture 100 that are not directly related to accessing the memory cells 105.

The local memory controller 160 may be operable to perform a write operation (e.g., a programming operation) on one or more memory cells 105 of the memory architecture 100. During a write operation, a memory cell 105 of the memory architecture 100 may be programmed to store a desired state (e.g., logic state, charge state). The local memory controller 160 may identify a target memory cell 105 on which to perform the write operation. The local memory controller 160 may identify a target word line 110 and a target digit line 115 coupled with the target memory cell 105 (e.g., an address of the target memory cell 105). The local memory controller 160 may activate the target word line 110 and the target digit line 115 (e.g., by applying a voltage to the word line 110 or digit line 115) to access the target memory cell 105. The local memory controller 160 may apply a signal (e.g., a write pulse, a write voltage) to the digit line 115 during the write operation to store a specific state (e.g., charge) in the capacitor 130 of the memory cell 105. The signal used as part of the write operation may include one or more voltage levels over a duration.

The local memory controller 160 may be operable to perform a read operation (e.g., a sense operation) on one or more memory cells 105 of the memory architecture 100. During a read operation, the state (e.g., a logic state or a charge state) stored in a memory cell 105 of the memory architecture 100 may be evaluated (e.g., read, determined, identified, or the like). The local memory controller 160 may identify a target memory cell 105 on which to perform the read operation. The local memory controller 160 may identify a target word line 110 and a target digit line 115 coupled with the target memory cell 105 (e.g., the address of the target memory cell 105). The local memory controller 160 may activate the target word line 110 and the target digit line 115 (e.g., applying a voltage to the word line 110 or digit line 115) to access the target memory cell 105. The target memory cell 105 may transfer a signal (e.g., a charge or a voltage) to the sense component 145 in response to biasing the access lines. The sense component 145 may amplify the signal. The local memory controller 160 may activate the sense component 145 (e.g., latch the sense component) and compare the signal received from the memory cell 105 to a reference (e.g., the reference 150). Based on that comparison, the sense component 145 may determine a logic state that is stored on the memory cell 105.

Memory devices in accordance with the memory architecture 100 may include various arrangements of memory cells 105 and supporting circuitry formed over a substrate, such as a semiconductor substrate (e.g., a wafer of crystalline semiconductor, such as crystalline silicon). For example, a memory device may include one or more layers or decks of memory cells 105 over a substrate (e.g., of a memory die), where a deck may refer to a plane or level in which memory cells 105 are provided above and parallel to the substrate. The one or more layers of memory cells 105 may be associated with various arrangements of access line conductors (e.g., conductor portions of a word line 110, conductor portions of a digit line 115), including access line conductors extending along one or more directions over a substrate, access line conductors along a direction from a substrate, or various combinations thereof. In some examples, circuitry for accessing the memory cells 105, such as circuitry of a row decoder 120, of a column decoder 125, of a sense component 145, of an input/output 155, of a local memory controller 160, may include transistors that are formed at least in part from doped portions of a substrate of a memory die (e.g., substrate-based transistors, transistors having channels formed from doped crystalline silicon or another semiconductor).

In an example, a memory device may include a first semiconductor die (e.g., including a first semiconductor substrate, a first memory die) associated with the memory cells 105 and corresponding access lines (e.g., word lines 110, digit lines 115) of the memory device, and a second semiconductor die (e.g., including a second semiconductor substrate, a second memory die) associated with at least a portion of access line driver circuitry of the memory device. The memory device may include various configurations of electrical contacts formed in contact with (e.g., coincident with or through) at least a portion of the first semiconductor die and at least a portion of the second semiconductor die that couple the access line driver circuitry of the second semiconductor die with the access lines of the first semiconductor die.

In some examples, a first semiconductor die may include word line conductors (e.g., at least a portion of word lines 110) that are each operable to access a respective set of one or more memory cells 105 (e.g., a row of memory cells, a group of memory cells, a cluster of memory cells, or the like) of the first semiconductor die. In some examples, the word line conductors of the first semiconductor die may be included in a two-dimensional arrangement along a first direction away from a substrate of the first semiconductor die and a second direction over the substrate of the first semiconductor die. In some examples, such an arrangement may include word line conductors having different extents along a third direction over the substrate of the first semiconductor die (e.g., in a tiered arrangement) to facilitate connections with electrical contacts formed between the semiconductor dies. In an example, the first semiconductor die includes a plurality of word line conductors arranged in a vertical stack on a substrate of the first semiconductor die. Each of the word line conductors may include respective branches that extend from respective trunks along a horizontal direction over the substrate. Each word line conductor can have a corresponding driver tab. When viewed as an assembly or stack of the word line conductors, the driver tabs can be tiered to facilitate connections with driver circuitry. In an example, each of the driver tabs can have like dimensions and can be provided adjacent to their respective word line conductor trunk.

In some examples, a second semiconductor die may include word line drivers (e.g., at least a portion of a row decoder 120) that are each operable to access (e.g., select, bias, drive) a respective word line conductor of the first semiconductor die. In some examples, word line drivers of the second semiconductor die may be included in a two-dimensional arrangement along a first direction and a second direction over a substrate of the second semiconductor die (e.g., an in-plane arrangement along the substrate). Each word line driver may include a respective set of one or more transistors, one or more of which may be formed at least in part from doped portions of a substrate of the second semiconductor die.

In some examples, the second semiconductor die may be located (e.g., placed, fixtured, attached, bonded, etc.) in contact with or otherwise adjacent to the first semiconductor die, and cavities may be formed through at least the second semiconductor die (e.g., through at least the substrate of the second semiconductor die) to expose a portion of the first semiconductor die. In some examples, such cavities may be coincident with respective conductors (e.g., landing pads, contact patches) of the second semiconductor die that are coupled with the access line drivers, and coincident with respective conductors of the first semiconductor die that are coupled with the access line conductors. The electrical contacts between the second semiconductor die and the first semiconductor die may be formed at least in part from forming (e.g., depositing) a conductive material in the cavities to thereby form a conductive pillar. In some other examples, electrical coupling between access line driver circuitry of the second semiconductor die and access lines of the first semiconductor die may additionally, or alternatively, be supported by other techniques, such as an electrical coupling between respective contacts of (e.g., at the surface of) the second semiconductor die, or the first semiconductor die, or both. Each word line driver circuit may be operable to bias a respective word line conductor based at least in part on a respective word line decoder signal.

In an example, providing access line driver circuitry in a second semiconductor die, different than a first semiconductor die that is associated with the access lines and corresponding memory cells, may increase an area available for substrate-based circuitry (e.g., by implementing multiple substrates) compared to memory devices that include a single semiconductor die (e.g., a single semiconductor substrate or single memory die). For example, such techniques may support leveraging substrate materials (e.g., crystalline semiconductor materials, crystalline silicon) for a greater quantity of components or larger components for circuitry such as the access line driver circuitry of the second semiconductor die, as well as other circuitry such as sensing circuitry, decoding circuitry, or other circuitry used for accessing or otherwise operating memory cells of a memory device, which may be implemented on the first semiconductor die, on the second semiconductor die, or various combinations thereof. In some examples, implementing such circuitry in multiple levels of substrate-based circuitry of a memory device may alleviate or mitigate area utilization challenges or routing challenges of a single semiconductor substrate, which may improve scaling in memory devices by supporting a greater quantity of memory cells (e.g., a greater quantity of decks) for a given footprint, among other advantages.

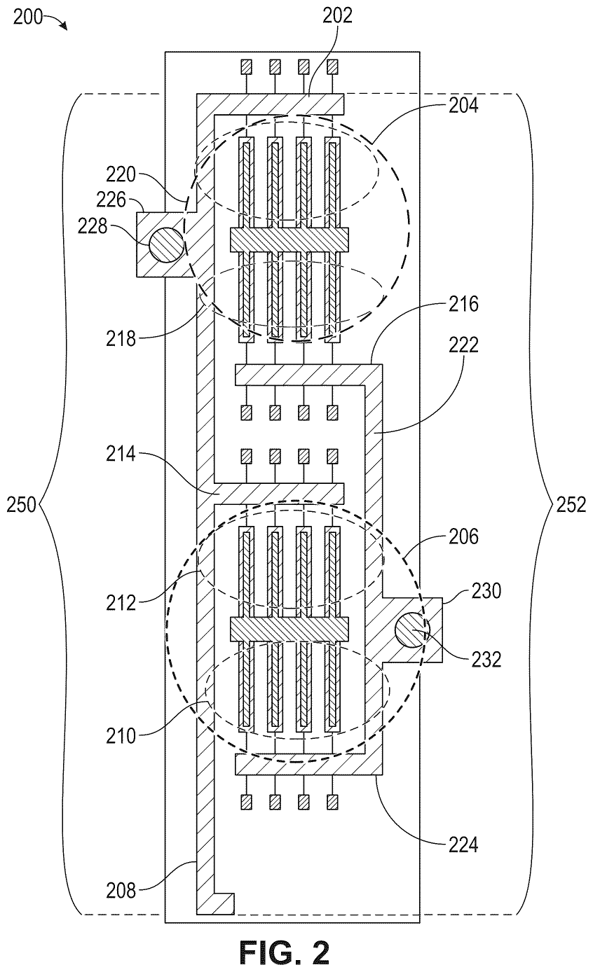

FIG. 2 illustrates generally a top view of a layer of a first region 200 of a memory device. The first region 200 includes a first word line 250 and a second word line 252 configured to access respective portions of a memory cell array. Branches of the first word line 250 are interleaved with branches of the second word line 252. In an example, the first word line 250 and the second word line 252 can be used separately and independently to access respective portions of the memory cell array. That is, particular cells in a particular layer of a memory cell array can be accessed in response to activation of a word line that corresponds to fewer than all of the cells in the particular layer of the array.

In an example, driver circuitry can be provided to activate the first word line 250 and the second word line 252. In an example, only some target cells in the particular layer of the array may need to be accessed at a given time. Accordingly, the word line corresponding to the target cells can be activated by its corresponding driver circuitry, and other driver circuitry can be idle or unused. In this example, the power consumed or used to activate the word line corresponding to the target cells can be less than a power that would otherwise be consumed or used to activate a word line that corresponds to a greater number (e.g., all) of the cells in the particular layer of the array.

In the example of FIG. 2, the first region 200 includes multiple cell groups in a first layer of memory cells of a memory array. The memory device can include or use multiple layers of memory cells. The memory cells include a first cell group 204 and a second cell group 206. In the illustrated example, each cell group is associated with branches of at least two word lines. For example, the first cell group 204 can be associated with, or accessed using, portions of the first word line 250 and the second word line 252.

The cell groups can be divided into different portions. For example, the first cell group 204 includes a first portion 220 and a second portion 218 of the first cell group 204. Similarly, the second cell group 206 includes a first portion 212 and a second portion 210 of the second cell group 206.

Each of the word lines in the example of FIG. 2 includes a respective trunk and branches. For example, the first word line 250 includes a first trunk 208 with a first branch 202 and a second branch 214 extending orthogonally form the first trunk 208. Similarly, the second word line 252 includes a second trunk 222 with a third branch 216 and a fourth branch 224 extending orthogonally from the second trunk 222. Thus, the branches may extend from their respective word line trunks and may connect to the memory cell groups. In the example of FIG. 2, the first branch 202 and the third branch 216 may be associated with or coupled to the first cell group 204 and the second branch 214 and the fourth branch 224 may be associated with or coupled to the second cell group 206.

The first trunk 208 and the second trunk 222 may represent a main body portion of the respective word lines from which the various branches extend. The branches may correspond to the word lines 110 described in FIG. 1, which may be used to perform access operations on the memory cells. The interleaved structure of the word line branches may allow for efficient use of space and improved access to memory cells. In other examples, memory cells may be additionally or alternatively accessed using the trunk portions of the word lines.

In an example, the first cell group 204 includes a first portion 220 of memory cells of the first cell group 204, and these cells are electrically coupled to, or accessed by, the first branch 202 of the first word line 250. The second portion 218 of the first cell group 204 is coupled to the third branch 216 of the second word line 252. In an example, a second cell group 206 includes a first portion 212 of the second cell group 206, and these cells are electrically coupled to, or accessed by, the second branch 214 of the first word line 250. The portion 210 of the second cell group 206 is coupled to the fourth branch 224 of the second word line 252, and so on. The first cell group 204 and the second cell group 206 can comprise cells in a particular layer of the memory cell array. In this manner, the branches of the second word line are interposed between and coplanar with the branches of the first word line.

In an example, the first region 200 includes a first driver tab 226, and a second driver tab 230. These driver tabs may be coupled to word line trunks and facilitate connection to driver circuitry. In an example, each driver tab extends orthogonally away from its associated word line trunk. Each driver tab can comprise a conductive platform at which, or with which, the word line can be coupled to other conductors or circuitry. In an example, the first region 200 includes a first pillar 228 coupled to the first driver tab 226 and a second pillar 232 coupled to the second driver tab 230. The first and second pillars 228, 232 can be conductive pillars that connect the respective driver tabs to other circuitry (e.g., driver circuitry). Driver tabs in different layers of the array can be offset from one another in the direction of the word line trunks. This arrangement allows for efficient use of space and improved access to memory cells.

FIG. 2 thus demonstrates a memory device with word lines structured with branches to interact with multiple respective cell groups. This branching structure of word lines may allow for a potentially higher density of memory cells within the array, while still maintaining the ability to selectively access individual memory cells or groups of cells. The interleaved branches may allow for memory cells from different cell groups to be accessed more efficiently, and using less power, thereby improving the overall performance of the memory device. Furthermore, the structure disclosed in FIG. 2 may support the implementation of a three-dimensional (3D) DRAM architecture with improved density and performance characteristics. This arrangement can be repeated in multiple layers, forming a stacked structure that efficiently uses the available space.

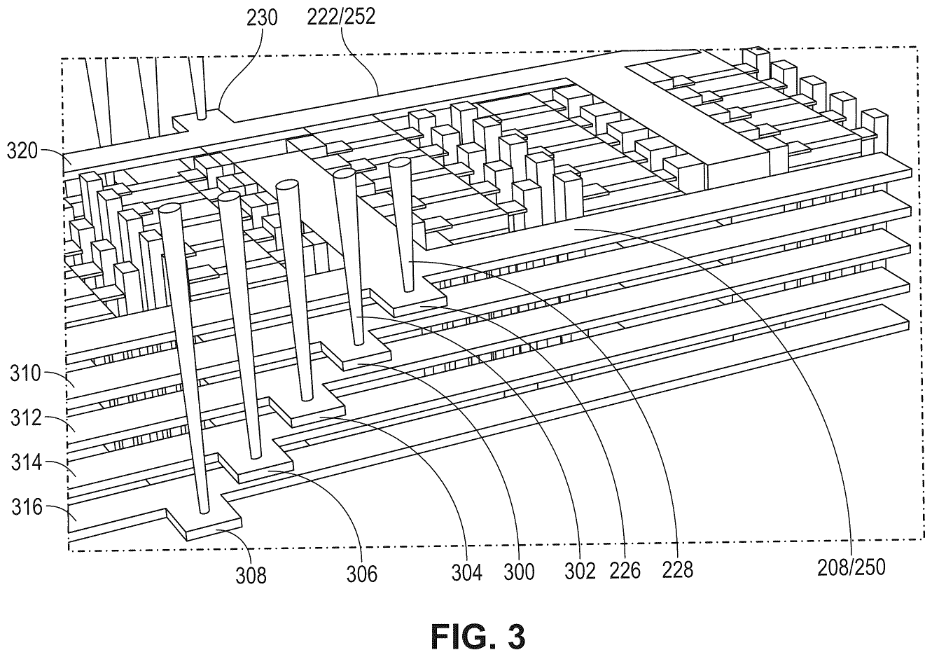

FIG. 3 illustrates generally a perspective view of an example of a three-dimensional memory device structure. The illustrated structure shows several layers arranged in a vertical stack. The structure includes a first layer 320, a second layer 310, a third layer 312, a fourth layer 314, and a fifth layer 316. While FIG. 3 illustrates five layers in the memory structure, it is understood that the structure may include as many layers as desired, necessary, or appropriate. Each layer comprises memory cells provided in a respective plane, and each layer includes respective interleaved word lines. In an example, each layer comprises an instance of the arrangement shown in the example of FIG. 2.

In an example, the first layer 320 includes the first word line 250 and the second word line 252. The first driver tab 226 is coupled to the first trunk 208 of the first word line 250, and the second driver tab 230 is coupled to the second trunk 222 of the second word line 252. In the example of FIG. 3, the first driver tab 226 is provided opposite to the second driver tab 230 with the memory cell array in between the tabs. Other arrangements or locations of the driver tabs can similarly be used.

FIG. 3 includes other driver tabs coupled with respective word line trunks in other layers of the device. For example, a word line in the second layer 310 includes a third driver tab 303, a word line in the third layer 312 includes a fourth driver tab 304, a word line in the fourth layer 314 includes a fifth driver tab 306, a word line in the fifth layer 316 includes a sixth driver tab 308, and so on. The driver tabs extend laterally away from their respective word line trunks at the different layers. In an example, each driver tab is a conductive extension of its respective trunk and each tab extends orthogonally relative to an axis of its corresponding trunk.

In an example, the memory array structure has a length characteristic and a width characteristic. The word line trunks extend along the length direction and the various branches extend from their respective trunks (e.g., orthogonally) in the width direction. In an example, one or more of the trunks extends continuously from a first end or edge of the memory array structure to an opposite second end or edge of the structure, thereby traversing an entire length of the memory array structure. In an example, the driver tabs of the respective different layers are positioned at different locations along the length direction of the trunks. In other words, the first driver tab 300 is provided at a first location that is a first distance from the first edge of the structure, and the third driver tab 322 is provided at a second location that is a second distance from the second edge of the structure, to thereby provide the driver tabs in staggered positions along a length of the memory array structure. This staggered arrangement of driver tabs may allow for efficient vertical connections such as through conductive pillars to respective word line driver circuits. This configuration supports the tiered structure that may be used in 3D DRAM while providing improved density and performance characteristics.

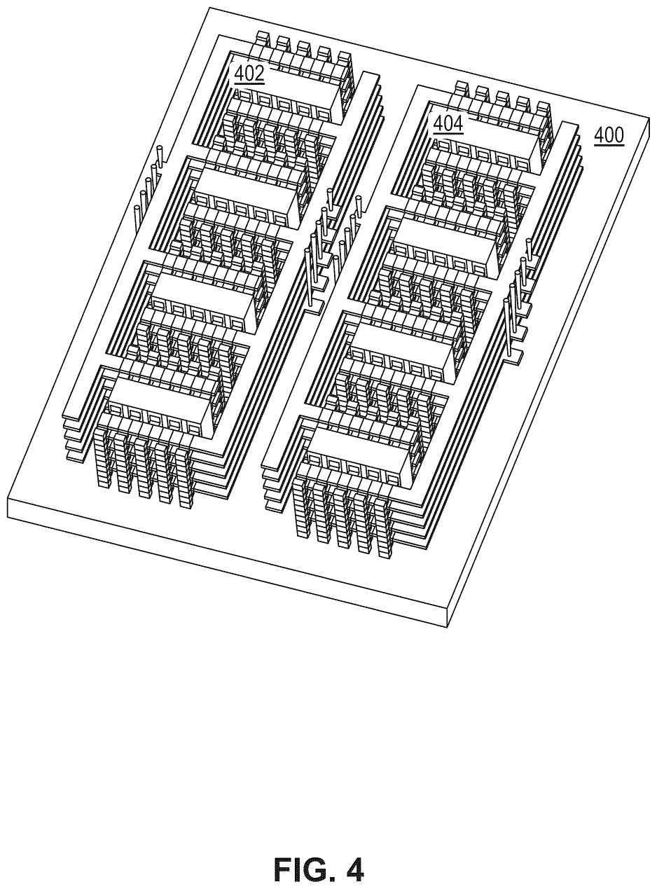

FIG. 4 illustrates a three-dimensional memory device with multiple memory cell arrays. FIG. 4 illustrates a substrate 400 on which a first memory cell array 402, a second memory cell array 404, and various other structures may be formed. The memory cell arrays 402 and 404 may be respective three-dimensional structures, each comprising multiple layers of memory cells stacked vertically (as described above with regard to FIG. 3). Each layer of the array may include word lines and memory cells. Various vertical structures in each array can include bit lines or other access lines for the memory cells.

In the example of FIG. 4, the arrays 402 and 404 may be substantially identical array instances and may be positioned side by side on the substrate 400. While two arrays are shown in FIG. 4, it is understood that a device may include additional arrays, which may be arranged in any suitable manner (e.g., in a grid). Furthermore, while arrays 402 and 404 may be identical (e.g., have the same number of layers, the same number of word lines, the same number of driver tabs and pillars, etc.), it is understood that the arrays need not be identical. For example, one array may have a different number of layers than the other, or the layers in one array may have a different number of word lines than the layers in the other array. Various structures in each array can include respective bit lines or other access lines for the memory cells of the particular array.

Each memory cell array (402 and 404) may include multiple cell groups and multiple layers of cells, similar to the structure shown in FIG. 2. The word lines in each array may include respective trunks and branches, with the branches extending orthogonally in a first direction from the trunks to connect to the memory cell groups, as described above. The word lines in each array may include respective driver tabs that extend orthogonally from the trunks in a second direction that is opposite to the first direction. The driver tabs can be arranged in a staggered configuration alongside a length direction of each memory cell array. In an example, driver tabs of the first memory cell array 402 can be adjacent to driver tabs of the second memory cell array 404, and an array-to-array distance can be minimized.

The arrangement of driver tabs the memory device design illustrated in FIGS. 2-4 offers significant advantages in terms of spatial efficiency and array density. By positioning the driver tabs along the sides of the memory arrays and staggering them along the length of each array, as illustrated in FIG. 4, the design allows for a more compact and efficient layout compared to other approaches. The configuration shown in FIG. 4 enables multiple memory arrays (such as arrays 402 and 404) to be placed directly adjacent to each other on the substrate 400, maximizing the utilization of available space.

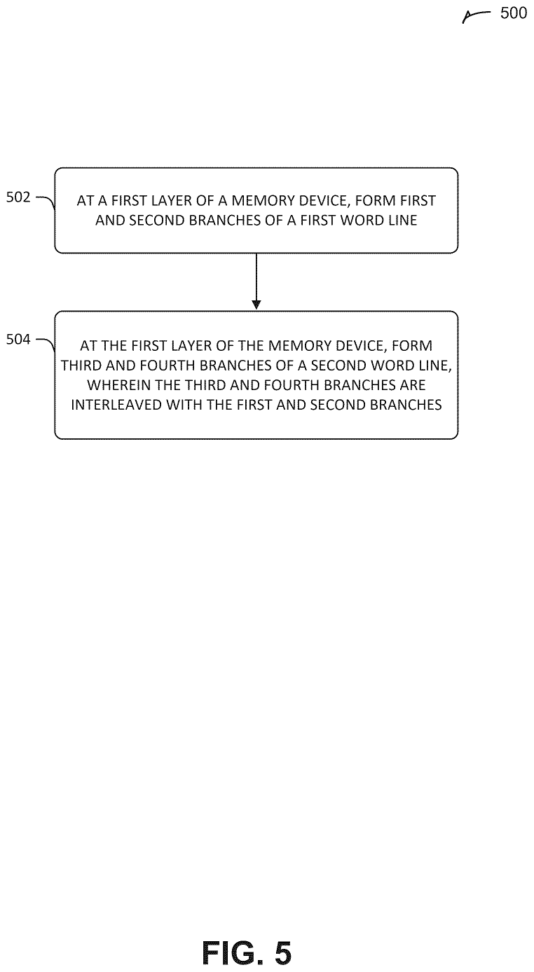

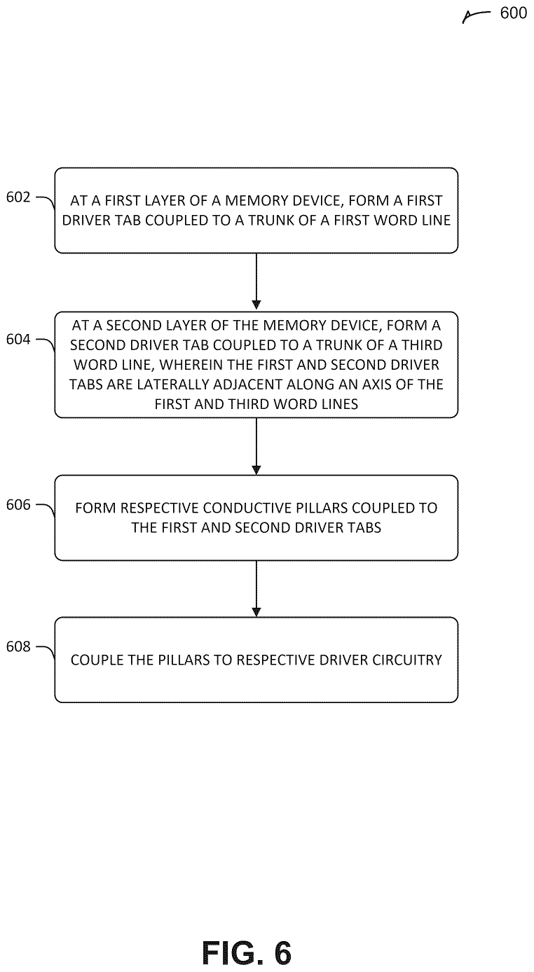

FIGS. 5 and 6 illustrate methods for forming word line structures in a memory device. The methods 500 and 600 can include or comprise a number of Operations or Steps. The Operations described herein are examples only, and the methods can omit one or more of the listed Operations, can repeat Operations, can include other Operations, or can execute the Operations concurrently, substantially simultaneously, or in another order, as appropriate or desired.

FIG. 5 illustrates a method 500 for forming interleaved word line branches in a memory device. At Operation 502, the method 500 may include forming first and second branches of a first word line at a first layer of a memory device. This operation may correspond to or be similar to forming the first branch 202 and second branch 214 extending orthogonally from the first trunk 208, as described in the discussion of FIG. 2.

At Operation 504, the method 500 may include forming third and fourth branches of a second word line at the first layer of the memory device, wherein the third and fourth branches are interleaved with the first and second branches. This operation may correspond to or be similar to forming the third branch 216 and fourth branch 224 extending orthogonally from the second trunk 222, as described in the discussion of FIG. 2.

The method 500 may further include coupling the first and third branches to a first cell group and coupling the second and fourth branches to a second cell group. For example, such as described above for FIG. 2, in which the first branch 202 and third branch 216 may be associated with or coupled to the first cell group 204, while the second branch 214 and fourth branch 224 may be associated with or coupled to the second cell group 206.

FIG. 6 illustrates a method 600 for forming driver tabs and conductive pillars in a three-dimensional memory device. At Operation 602, the method 600 may include forming a first driver tab coupled to a trunk of a first word line at a first layer of a memory device. This operation may correspond to or be similar to forming the first driver tab 226, as shown in FIGS. 2 and 3, and which is coupled to a word line trunk and to driver circuitry.

At Operation 604, the method 600 may include forming a second driver tab coupled to a trunk of a third word line at a second layer of the memory device, wherein the first and second driver tabs are laterally adjacent along a length axis of the first and third word lines. This operation may correspond to or be similar to forming the third driver tab 300 as shown in FIG. 3.

At Operation 606, the method 600 may include forming respective conductive pillars coupled to the first and second driver tabs. This operation may correspond to forming the first pillar 228 and second pillar 232 as shown in FIG. 2, which are conductive pillars that connect the driver tabs to driver circuitry.

At Operation 608, the method 600 may include coupling the pillars to respective driver circuitry. This operation includes forming the electrical connection between the conductive pillars and the underlying word line driver circuits, enabling the transfer of word line drive signals from the driver circuitry to the word lines through the pillars and driver tabs. This operation completes the vertical connection pathway from the word line driver circuits to the word lines in different layers of the three-dimensional memory device structure.

The methods 500 and 600 support the implementation of a three-dimensional (3D) DRAM architecture with improved density and performance characteristics. These arrangements can be repeated in multiple layers, forming a space-efficient stacked structure. The three-dimensional structures discussed herein allow for a higher density of memory cells per unit area and an ability to selectively access individual memory cells or groups of cells.

### ADDITIONAL NOTES & EXAMPLES

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is to allow the reader to quickly ascertain the nature of the technical disclosure and is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the embodiments should be determined with reference to the appended claims, along with the full scope of equivalents to which such claims are entitled.

What is claimed is:

1. A memory device comprising:
a plurality of word lines comprising a portion of a first layer of the memory device, including:
a first word line comprising a first trunk and at least first and second branches that extend from, and are electrically coupled to, the first trunk; and
a second word line comprising a second trunk and at least third and fourth branches that extend from, and are electrically coupled to, the second trunk, wherein the second word line is electrically decoupled from the first word line;
wherein the first and second branches of the first word line are interleaved with the third and fourth branches of the second word line in the first layer of the memory device.

2. The memory device of claim 1, wherein the first trunk is substantially parallel to, and coplanar with, the second trunk in the first layer of the memory device, wherein each memory cell comprises a capacitor and a switching component and wherein the capacitor is configured to store a charge representative of a programmable state.

3. The memory device of claim 2, wherein the first and second branches extend perpendicularly from the first trunk in a first direction, and wherein the third and fourth branches extend perpendicularly from the second trunk in a second direction that is opposite to the first direction.

4. The memory device of claim 3, comprising:
a first driver tab coupled to the first trunk and extending laterally away from the first trunk in the second direction;
a second driver tab coupled to the second trunk and extending laterally away from the second trunk in the first direction; and
respective pillars coupled to the first driver tab and the second driver tab, wherein the respective pillars are configured to receive respective word line drive signals from a word line driver of the memory device, wherein each word line driver comprises a plurality of transistors formed on a second semiconductor die, and wherein each transistor is operable to bias a respective word line conductor based on one or more word line decoder signals.

5. The memory device of claim 4, comprising:
a third word line comprising a portion of a second layer of the memory device, the third word line comprising a third trunk and a third driver tab coupled to the third trunk, wherein the third driver tab extends laterally away from the third trunk in the second direction;
wherein the third driver tab and the first driver tab are laterally offset in an axial direction of the first trunk and the third trunk.

6. The memory device of claim 5, wherein the first layer and the second layer are adjacent layers offset in a vertical direction, and wherein branches of the first word line in the first layer and third word line in the second layer have substantially identical dimensions, wherein the first and second pillars are formed by depositing a conductive material in one or more cavities that extend through at least a portion of the second semiconductor die.

7. The memory device of claim 5, wherein the first word line and the third word line have a substantially identical surface area characteristic.

8. The memory device of claim 5, wherein the first word line, the second word line, and the third word line have a substantially identical surface area characteristic.

9. The memory device of claim 1, comprising:
a first group of memory cells in the first layer, wherein the first group of memory cells are electrically coupled to the first branch of the first word line.

10. The memory device of claim 9, comprising:
a third group of memory cells in the first layer, wherein the third group of memory cells are electrically coupled to the first word line.

11. The memory device of claim 1, wherein the first and third branches are coupled to respective memory cell groups of a first memory cell array in the first layer, and wherein the second and fourth branches are coupled to respective memory cell groups of a second memory cell array in the first layer.

12. A memory device, comprising:
a first plurality of interleaved word lines comprising a portion of a first layer of the memory device, including at least a first word line and a second word line, wherein each word line includes a respective trunk and one or more respective branches extending perpendicularly from the respective trunk;
a first group of memory cells in the first layer and electrically coupled to a first branch of the first word line;
a second group of memory cells in the first layer and electrically coupled to a second branch of the first word line; and
a third group of memory cells in the first layer and electrically coupled to a first branch of the second word line, wherein the first branch of the second word line is interposed between, and coplanar with, the first branch and second branch of the first word line.

13. The memory device of claim 12, wherein the first branch of the first word line is configured to selectively access or activate one or more individual memory cells of the first group of memory cells.

14. The memory device of claim 12 wherein the memory device is configured to simultaneously activate or deactivate multiple memory cells or multiple sets of memory cells through activation or deactivation of corresponding branches to which the multiple memory cells or multiple sets of memory cells are connected.

15. The memory device of claim 12, comprising:
a second plurality of interleaved word lines comprising a portion of a second layer of the memory device including at least a third word line and a fourth word line, wherein each respective word line in the second layer of the memory device includes a respective trunk and one or more respective branches extending perpendicularly from the respective trunk; and
a plurality of bit lines extending orthogonally to the word lines and between the first and second layers of the memory device, wherein each of the bit lines is coupled to a respective memory cell in the first layer and a respective memory cell in the second layer.

16. The memory device of claim 15, wherein the branches of the word lines in the second layer are oriented in a direction opposite to the branches of the word lines in the first layer.

17. The memory device of claim 15, wherein each word line trunk in the first layer and the second layer is coupled to a respective driver tab extending laterally from an edge of the memory device, wherein the respective driver tabs in the first layer are offset from the respective driver tabs in the second layer along the edge of the memory device, and wherein each of the respective driver tabs is coupled to a corresponding word line driver circuit.

18. An apparatus comprising:
a first semiconductor die comprising a plurality of word line conductors arranged in a vertical stack away from a substrate of the first semiconductor die, each word line conductor of the plurality of word line conductors including respective branches that extend along a horizontal direction over the substrate, wherein each branch is operable to access respective memory cells of the first semiconductor die, wherein branches of a first word line conductor are interleaved with branches of a second word line conductor, and the first and second word line conductors occupy a first layer in the vertical stack;
a second semiconductor die comprising a plurality of word line driver circuits, each word line driver circuit of the plurality of word line driver circuits operable to bias a respective word line conductor of the plurality of word line conductors based at least in part on a first word line decoder signal and a respective second word line decoder signal of a plurality of second word line decoder signals; and
a plurality of electrical contacts, each electrical contact of the plurality of electrical contacts coupling a respective word line conductor of the plurality of word line conductors with a respective word line driver circuit of the plurality of word line driver circuits.

19. The apparatus of claim 18, wherein the plurality of electrical contacts comprise:
a first pillar that extends vertically from a first driver tab of the first word line conductor in the first layer of the vertical stack; and
a second pillar that extends vertically from a second driver tab of a third word line conductor in a second layer of the vertical stack adjacent to the first layer of the vertical stack.

20. The apparatus of claim 18, wherein each word line driver circuit of the plurality of word line driver circuits comprises:
a first transistor having a first channel portion electrically coupled between the respective word line conductor and an output of a word line decoder associated with the first word line decoder signal, and having a first gate portion electrically coupled with an output of the word line decoder associated with the respective second word line decoder signal; and
a second transistor having a second channel portion electrically coupled between the respective word line conductor and a word line deselection voltage source and having a second gate portion electrically coupled with the output of the word line decoder associated with the respective second word line decoder signal.
